(19) United States
(12) Patent Application Publication
(10) Pub. No.: US 2018/0158762 A1
(43) Pub. Date: Jun. 7, 2018

(54) SEMICONDUCTOR DEVICE

(71) Applicant: KABUSHIKI KAISHA TOSHIBA, Tokyo (JP)

(72) Inventor: Tatsuo TONEDACHI, Yokohama Kanagawa (JP)

(21) Appl. No.: 15/688,572

(22) Filed: Aug. 28, 2017

(30) Foreign Application Priority Data
Dec. 6, 2016 (JP) 2016-236918

(51) Int. Cl. H01L 23/495; H01L 23/31; H01L 23/00

(52) U.S. Cl. CPC H01L 23/49568; H01L 23/3121; H01L 24/48; H01L 23/49555; H01L 23/49513; H01L 2224/29147; H01L 24/33; H01L 2224/48175; H01L 2224/32245; H01L 2224/33181; H01L 24/32

(57) ABSTRACT

A semiconductor device includes a semiconductor chip having a first surface, a first electrode and a second electrode provided on the first surface, a wiring electrically connected to the first electrode at the first surface, a first metal layer on the first surface and directly contacting the second electrode, a thickness of the first metal layer in a direction orthogonal to the first surface being greater than a height of a topmost portion of the wiring in the first direction from the first surface, and a resin package contacting the semiconductor chip, the first metal layer, at least a portion of the wiring, and a first portion of the first surface and leaving a second portion of the first surface exposed.

### CROSS REFERENCE TO RELATED APPLICATION

This application claims the benefit of and priority to the Japanese Patent Application No. 2016-236918 filed on Dec. 6, 2016, the entire contents of which are incorporated herein by reference.

### FIELD

Embodiments described herein relate generally to a semiconductor device.

### BACKGROUND

A semiconductor device having a power semiconductor package dissipates heat from surfaces of connection conductors exposed from upper and lower surfaces of the power semiconductor package. A connection conductor such as a lead frame is soldered to a semiconductor chip. A metal spacer may be provided between the connection conductor and the semiconductor chip to dissipate heat efficiently. However, since a heat transfer rate via a metal spacer soldered to the semiconductor chip is low, heat generated in the semiconductor chip may not be transferred to the spacer sufficiently, resulting in further heating and consequent destruction of the semiconductor chip in a short time due to a large thermal resistance.

In a semiconductor chip having IGBT (Insulated Gate Bipolar Transistor), for example, a metal spacer is electrically connected to an emitter electrode provided on the upper surface of the semiconductor chip. One the upper surface of the semiconductor chip, a gate electrode connected to a wiring and a portion having a different voltage from that of the emitter electrode are further provided. It is required that short-circuit, for example, via a solder, between the emitter electrode and the portion having a different voltage from that of the emitter electrode or the gate electrode be prevented. Therefore, a size of a metal spacer is limited so as to be smaller than an area of the upper surface of the emitter electrode. Alternatively, the emitter electrode may be sufficiently spaced from the gate electrode, resulting in an increase in an area of the semiconductor chip. It is desired that the semiconductor device has reliability in preventing short-circuit between the electrodes and the improved heat dissipation efficiency.

### BRIEF DESCRIPTION OF THE DRAWINGS

FIG. 1 is a schematic perspective view depicting a semiconductor device.

FIG. 2 is a cross-sectional view taken along the line II-II of the semiconductor device depicted in FIG. 1.

FIG. 3 is a diagram illustrating an inside of a semiconductor device and a perspective view depicting a configuration of a semiconductor chip with a metal layer.

FIG. 4 is a plane view depicting an inside configuration of the semiconductor device depicted in FIG. 3.

FIG. 5 is a cross-sectional view depicting an enlarged part of the semiconductor device depicted in FIG. 2.

FIG. 6 is a simulation result of a heat resistance.

FIG. 7 is a cross-sectional view depicting a modified example of a semiconductor device.

FIG. 8 is a diagram depicting a manufacturing method of a semiconductor device.

### DETAILED DESCRIPTION

In some embodiments of the present disclosure, a semiconductor device is able to have a reliability and improve a heat dissipation efficiency.

In some embodiments according to one aspect, a semiconductor device includes a semiconductor chip having a first surface, a first electrode and a second electrode provided on the first surface, a wiring electrically connected to the first electrode at the first surface, a first metal layer on the first surface and directly contacting the second electrode, a thickness of the first metal layer in a direction orthogonal to the first surface being greater than a height of a topmost portion of the wiring in the first direction from the first surface, and a resin package contacting the semiconductor chip, the first metal layer, at least a portion of the wiring, and a first portion of the first surface and leaving a second portion of the first surface exposed.

Example embodiments of the present disclosure will described hereinafter with reference to an accompanying drawings. The embodiments are not intended to limit the scope of the disclosure.

### First Embodiment

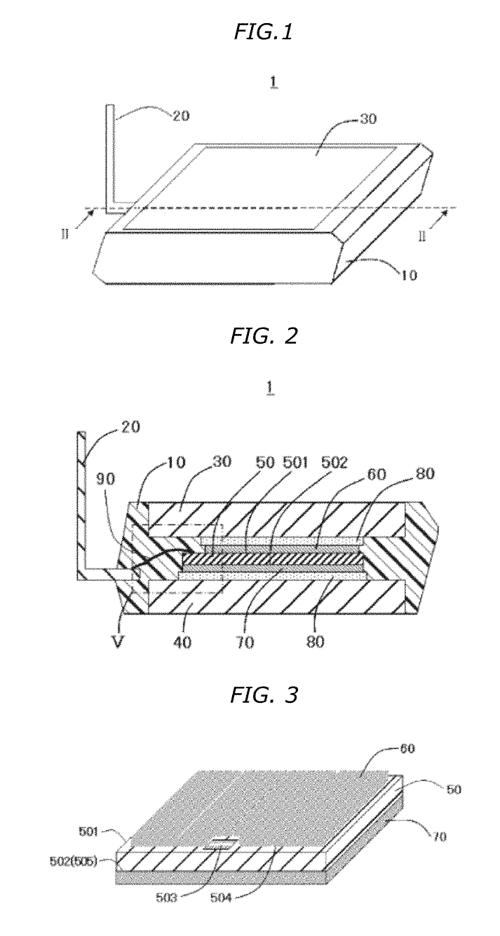

FIG. 1 is a schematic perspective view depicting a semiconductor device according to a first embodiment. A semiconductor device 1 includes a power semiconductor package for heat dissipation. The semiconductor package may be a surface mounted type. The semiconductor device 1 includes a package 10 and lead frames 20 and 30. The lead frame 20 is drawn out from a side of the package 10. A portion of the lead frame 30 is sealed with the package 10. The other portion of the lead frame 30, that is, at least the portion of the surface, is exposed from an upper surface of the package 10. A lead frame, which is described as below, is provided on a lower surface of the package 10. The package 10 includes resin and seals a portion of the lead frame 20, the portion of the lead frame 30, and a semiconductor chip, which is described as below, and the like by using a transfer mold method. As described above, the semiconductor device 1 in the package 10 dissipates heat from the both surfaces of the package 10.

FIG. 2 is a cross-sectional view taken along the line II-II of the semiconductor device 1 depicted in FIG. 1. The semiconductor device 1 includes the package 10, the lead frames 20, 30, and 40, the semiconductor chip 50, a metal layer 60, referred to more generally as a first layer, a metal layer 70, a solder 80, and a wiring 90. The lead frames 20, 30, and 40 include copper as a main material. A metal material such as aluminum may also be used for the lead frames. In this case, a surface of aluminum may be plated with nickel and gold so as to be connected with the solder. A portion of the lead frame 40 is sealed within the package 10 in the same way as the lead frame 30. The other portion, that is, at least the portion of the surface of the lead frame 40 is exposed from the lower surface of the package 10 to constitute the portion of the lower surface of the package 10. The semiconductor chip 50 includes IGBT, for example. An upper surface 501, which may be more generally referred as a first surface, of the semiconductor chip 50 is directly attached to a lower surface of the metal layer 60, that is, touching the lower surface of the metal layer 60. An upper surface of the metal layer 60 is connected to the lead frame 30 via the solder 80. A lower surface 502, which may be referred to more generally as a second surface of the semiconductor chip 50, is directly attached to an upper surface of the metal layer 70. That is, the semiconductor chip 50 is interposed between the metal layers 60 and 70 via the solder 80 and the stacked structure thereof is interposed between the lead frames 30 and 40. The wiring 90 connects the gate electrode 503 with the lead frame 20.

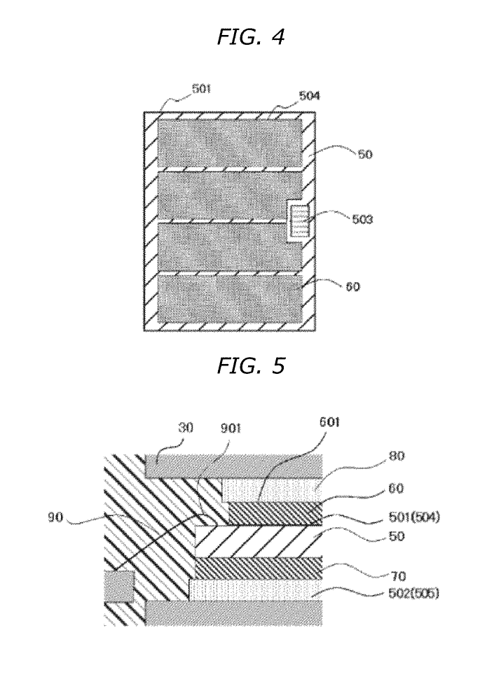

FIG. 3 is a diagram illustrating an inside of the semiconductor device 1 according to the first embodiment and a perspective view depicting a configuration of the semiconductor chip 50 with metal layers 60 and 70. FIG. 4 is a plane view depicting an inside configuration of the semiconductor device 1 depicted in FIG. 3. A shown in FIG. 3 and FIG. 4, a gate electrode 503, which may be more generally referred to as a first electrode, and an emitter electrode 504, which may be more generally referred to as a second electrode, are provided on the upper surface 501 and may include aluminum. The gate electrode 503 is provided at a center of an end portion of the upper surface 501. The emitter electrode 504 is spaced apart from the gate electrode 503 and surrounds three sides of the gate electrode 503. The emitter electrode 504 is provided directly beneath the metal layer 60 in FIG. 3 and FIG. 4. The emitter electrode 504 is separated into four parts and a gate wiring, which is not specifically depicted in the figures, is arranged between the four parts. The emitter electrode 504 may be separated into five parts or more, or three parts or less. A guard ring, which is not specifically depicted in the figures, is provided on a peripheral portion of the semiconductor chip 50. The metal layer 60 provided on the emitter electrode 504 contains copper as a main material and is formed by electric plating or electroless plating. The metal layer 60 is directly attached to the emitter electrode 504 and covers an entire upper surface of the emitter electrode 504. A collector electrode 505 is provided on an entire lower surface 502 of the semiconductor chip 50 and may contain aluminum. The metal layer 70 provided on the collector electrode 505 contains copper as a main material and is formed by electric plating or electroless plating the same as the metal layer 60. The metal layer 70 is directly attached to the collector electrode 505 and covers the entire upper surface of the collector electrode 505.

FIG. 5 is a cross-sectional view showing an enlarged part of the semiconductor device depicted in FIG. 2. A position of an upper surface 601 of the metal layer 60 is higher than a position of a top portion 901 of the wiring 90 which is formed by bonding. Thus, the upper surface 601 is closer to the lead frame 30 than is the top portion 901 of the wiring 90. A thickness of the metal layer 60 is larger than a length from the upper surface 501 of the semiconductor chip 50, that is, the upper surface of the emitter electrode 504 to the top portion 901 of the wiring 90. The thickness of the metal layer 60 is 50 μm (micro meter) or more, more likely, 100 μm or more. Thereby, the top portion 901 is not in contact with the lead frame 30 or the wiring 90 is not in contact with the solder 80 which is protruded from a gap between the metal layer 60 and the lead frame 30 to prevent the short circuit. Also, the metal layer 60 is directly attached to the emitter electrode 504 and covers the entire upper surface of the emitter electrode 504. A peripheral portion of the metal layer 60 can be provided so as to coincide with the peripheral of the emitter electrode 504. Thus, heat is effectively transferred from the entire upper surface of the emitter electrode 504 to the metal electrode 60 to effectively dissipate heat from the semiconductor chip 50. The solder which would be between the metal layer 60 and the emitter electrode 504 in a conventional case is omitted. Therefore, the solder, which has a lower heat transfer rate than that of copper, does not control the rate of heat transfer and the short circuit is prevented between the solder and the gate electrode 503 or between the solder and a portion having a different voltage to the emitter electrode 504. Copper may be used as the main material of the metal layer 60, and the metal layer 60 can be formed by electric plating or electroless plating of copper. Therefore, the metal layer 60 is formed to have a thickness of 50 μm or more and is directly formed on the emitter electrode without using solder. In general, aluminum has a lower heat transfer rate than that of copper. Also, it is difficult to form aluminum with a thickness of 50 μm or more because forming and removing a resist with a thick film thickness is difficult in the aluminum sputtering film forming process. The configuration described above has reliability and improves the heat dissipation efficiency. The metal layer 70, which has the same material and the same thickness as the metal electrode 60, may be provided on the lower surface 502 of the semiconductor chip 50. Thus, a warp in the semiconductor chip 50 can be alleviated because a stress due to a difference in linear expansion coefficients between substrates, for example, between Si and SiC, is eliminated. Specifically, a stress between the semiconductor chip 50 and the metal layer 60 is offset by the stress between the semiconductor substrate 50 and the metal layer 70. The metal layer 70 is directly attached to the collector electrode 505, which is provide on the lower surface of the semiconductor chip 50, and covers the entire upper surface of the collector electrode 505. A peripheral portion of the metal layer 70 can be provided so as to coincide with the periphery of the collector electrode 505 to efficiently dissipate heat from the entire upper surface of the collector electrode 505 to the metal layer 70. The metal layers 60 and 70 are each connected directly to the upper surface 501 and the lower surface 502 of the semiconductor chip without a solder. In a conventional structure, a solder is used between the semiconductor chip and the metal layer, and between the metal layer and the lead frame, a control in a reflow process between the semiconductor chip and the metal layer is difficult because. In the first embodiment, the metal layer 60 is directly connected and provided on the semiconductor chip 50 in the semiconductor device 1. Therefore the height control of the metal layer to the semiconductor chip is not necessary to be considered. The semiconductor device in the first embodiment can obtain the high reliability.

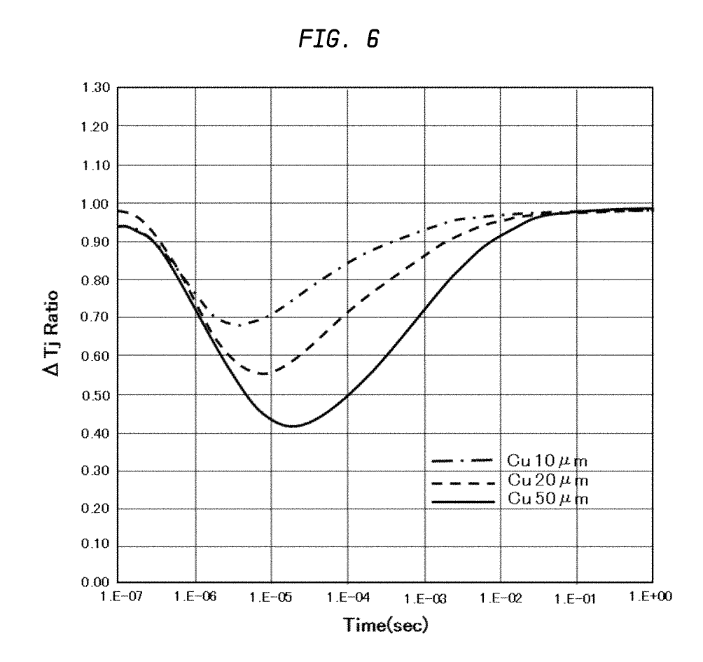

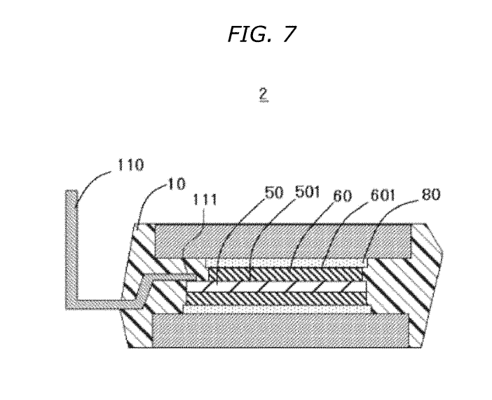

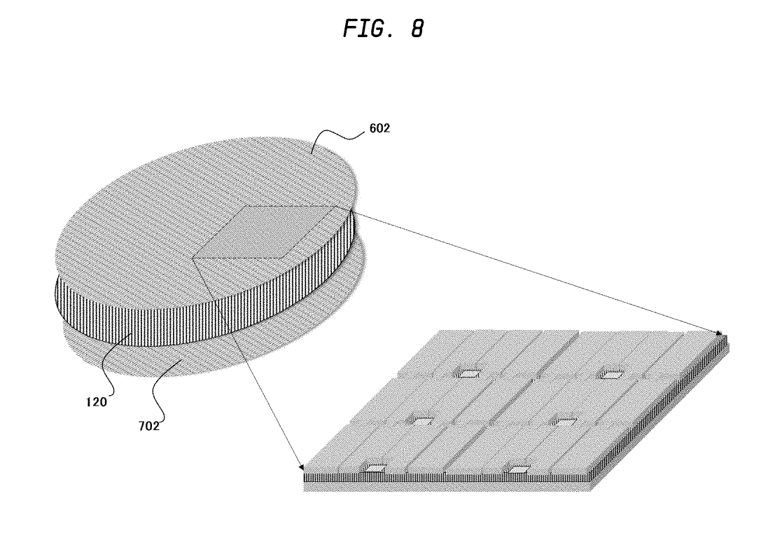

FIG. 6 is a simulation result of a heat resistance according to the first embodiment. In this simulation, a conventional structure without a metal layer, which is provided on an emitter electrode including aluminum as the main material, is used as a reference structure. A structure with a metal layer, which is provided on the emitter electrode and includes copper as the main material, is described in detail as an investigated structure. A variation rate of a surface temperature with the lapse of time in the investigated structure is illustrated in FIG. 6. A lateral axis represents times (sec) and a longitudinal axis represents a ratio of the surface temperatures in the investigated configuration in comparison to the reference structure, ΔTj ratio. The thickness of the metal layer in the investigated structure is 10 μm, 20 μm, or 50 μm. A surface opposite to the surface in contact with the emitter electrode is insulated from heat and does not dissipate heat. As is evident from FIG. 6, ΔTj ratio takes a minimum value of about 62% when the metal layer has a thickness of 50 μm. The metal layer can efficiently absorb heat which is generated from the semiconductor chip in a short time. In the reference structure, the semiconductor chip is possible to be short-circuited in the order of 0.01 m sec and broken down due to a large heat resistance. The break down can occur before an operation of a protection circuit for preventing heating which is provided in the semiconductor device. However, ΔTj ratio is beyond 50% in 0.01 mm sec when the metal layer has a thickness of 50 μm in the investigated structure. Therefore, the metal layer in the investigated structure can absorb heat which is generated from the semiconductor chip in a short time more efficiently than the reference structure and the semiconductor chip can be prevented from breaking down before the operation of the protection circuit for preventing heating. After 0.01 m sec, the protection circuit for preventing heating operates to prevent excessive heating. As described above, in the semiconductor chip 1 according to the first embodiment, the metal layer has the thickness of 50μm or more, and more preferable 100 μm or more so that the lead frame is not in contact with the top portion of the wiring. Thus, the reliability and heat dissipation property in the short time can be improved.

In the semiconductor device 1 according to the first embodiment, the metal layer 60 and 70 which include copper as the main materials are directly attached to an upper electrode and a lower electrode respectively, and are provided on the entire upper surface of the electrodes to dissipate heat efficiently. The metal layer with the thickness which is described above can prevent a contact between the lead frame 30 and the wiring 90, or the solder 80 and the wiring 90 to obtain the semiconductor device with high reliability, and the heat dissipation in a short time before the operation of the protection circuit can become possible. In the semiconductor device 1, the solder 80 is used for a connection between the lead frame 30 and the metal layer 60, and between the lead frame 40 and the metal layer 70. However, a connection formed by a diffusion of metals such as Ag (silver) nanopaste or an alloy such as CuSn may be used. Silicon is used as a material for the semiconductor chip 50. However, GaN (Gallium nitride) or SiC (silicon carbonate) may be used. An IGBT is used in the semiconductor chip. However, a MOSFET (Metal Oxide Semiconductor Field Effect Transistor), a HEMT (High Electron Mobility Transistor), diode, etc. may be used. A module with one chip is used for the semiconductor chip 1. However, a module with two chips may be used for the semiconductor chip 1. A module with the different chips such as IGBT and FRD (First Recovery Diode) may also be used. A plurality of the semiconductor chips can commonly use a lead frame exposed from a surface of the module and a metal layer connected to the lead frame via a solder when a voltage on upper surfaces of the plurality of semiconductor chips in the module is the same. Therefore, the module with the plurality of the semiconductor chips that is similar to the semiconductor device depicted in FIG. 2 can be obtained. In the module, a maximum size of lead frame in the allowable installation range on the upper surface of the module the can be used. For example, in a conventional semiconductor chip formed on a substrate which includes SiC, has upper limit in the size due to large crystal defect. However, the module according to the first embodiment can include a plurality of the semiconductor chips on a SiC substrate using a common lead frame.

### Modified Example According to the First Embodiments

The gate electrode 503 of the semiconductor chip 50 in the semiconductor device 1 according to the first embodiment is connected to the lead frame 20 via the wiring 90. In the present modified embodiment, the gate electrode 503 is connected to a lead frame 110 by a reflow soldering. In this case, the position of the upper surface 601 of the metal layer 60 is higher than a positon of an upper surface 111 of the lead frame 110 inside of the package 10. That is, the upper surface 601 is closer to the lead frame 30 than the upper surface 111 of the lead frame 110, and the thickness of the metal layer 60 is larger than a distance between the upper surface 501 and the upper surface 111 inside of the package 10. The thickness of the metal layer 60 is 50μm or more, more preferably, 100μm or more. Therefore, the lead frame 111 is not in contact with the lead frame 30 or the solder 80 to be short-circuited. The modified example has the same effect as the first embodiment.

### Second Embodiment

The metal layers 60 and 70 are formed by electric plating or electroless plating of the semiconductor chip 50 in the first embodiment as described above. In a second embodiment, the metal layer is a copper plate that is pressure bonded to a wafer at a high temperature before the wafer is divided into semiconductor chips. FIG. 8 is a diagram illustrating a manufacturing method of the semiconductor device according to the second embodiment. A metal layer 602 is formed on an upper surface of a wafer 120 after an IGBT is formed on the wafer 120. The metal layer 602 includes copper as a main material and is patterned beforehand so as to be the same shape as the upper surface of the emitter electrode. The metal layer 602 has a thickness of 50μm or more, more preferably, 100μm or more. A metal layer 702 of a copper plate having the same surface shape as the wafer 120 is provided on an entire lower surface of the wafer 120. The metal layer 702 has a substantially similar thickness as the metal layer 602. The metal layers 602 and 702 are bonded to the wafer 120 via an alloy of AuSn (gold and tin) at a high temperature by pressing. Thus, the semiconductor chip 50 interposed between the metal layer 602 and 702 can obtained by dicing. The wafer 120 is easily diced by etching and removing a portion of the metal layer 702 along a dicing line. The subsequent manufacturing processes in the second embodiment are the same as the first embodiment. The semiconductor device which is formed by the manufacturing process according to the second embodiment has the same effect as the semiconductor device according to the first embodiment.

### Modified Example of the Second Embodiment

The metal layer 602 formed on the surface of the wafer 120 is patterned beforehand in the second embodiment. A copper plate which is not patterned in advance is bonded to the wafer 120 via the alloy of AuSn at a high temperature in the modified example of the second embodiment. A portion of the copper plate corresponding to the gate electrode, a peripheral portion of the chip, and the dicing line are removed by etching to obtain the metal layer in a predetermined shape. The semiconductor chip is formed by dicing along the dicing line. The wafer 120 is easily diced by etching and removing the portion of the metal layer 702 provided on the lower surface of the wafer 120 beforehand. The subsequent manufacturing processes in the modified example of the second embodiment are the same as the first embodiment. The semiconductor device which is formed by the manufacturing process according to the modified example of the second embodiment has the same effect as the semiconductor device according to the first embodiment. While certain embodiments have been described, these embodiments have been presented by way of example only, and are not intended to limit the scope of the disclosure. Indeed, the methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A semiconductor device, comprising:
a semiconductor chip having a first surface;
a first electrode and a second electrode provided on the first surface;
a wiring electrically connected to the first electrode at the first surface;
a first metal layer on the first surface and directly contacting the second electrode, a thickness of the first metal layer in a direction orthogonal to the first surface being greater than a height of a topmost portion of the wiring in the first direction from the first surface; and
a resin package contacting the semiconductor chip, the first metal layer, at least a portion of the wiring, and a first portion of the first surface and leaving a second portion of the first surface exposed.

2. The semiconductor device according to claim 1, further comprising:
a second metal layer directly attached to a second surface of the semiconductor chip, the second surface being opposite to the first surface, the second metal layer having a thickness in the first direction substantially equal to the thickness of the first metal layer; and
a lead frame portion electrically connected to the second metal layer and having a portion exposed from the resin package.

3. The semiconductor device according to claim 2, wherein
the first metal layer comprises copper, and
the second metal layer comprises copper.

4. The semiconductor device according to claim 1, wherein the first metal layer comprises copper.

5. The semiconductor device according to claim 1, wherein
the resin package is a surface mounted type.

6. The semiconductor device according to claim 1, wherein the thickness of the first metal layer is 50μm or more.

7. The semiconductor device according to claim 1, wherein the first metal layer is one of an electrically plated layer or an electrolessly plated layer.

8. The semiconductor device according to claim 1, wherein the first metal layer is connected to a lead frame portion by a silver nanopaste.

9. The semiconductor device according to claim 1, wherein the first metal layer is connected to the second electrode by an alloy of gold and tin.

10. The semiconductor device according to claim 1, wherein the second electrode is provided in at least two portions spaced from each other on the first surface and the first metal layer is provided in corresponding portions such that a portion of the first surface between the at least two portions of the second electrode is left uncovered by the first metal layer.

11. The semiconductor device according to claim 1, further comprising:
a lead frame portion soldered to the first metal layer and having a surface exposed from the resin package.

12. The semiconductor device according to claim 1, wherein the wiring is a bonding wire.

13. The semiconductor device according to claim 1, wherein the wiring is a lead frame portion.

14. A semiconductor device, comprising:
a semiconductor chip comprising having a first surface;
a first electrode and a second electrode provided on a the first surface;
a wiring electrically connected to the first electrode at the first surface;
a first metal layer on the first surface and contacting the second electrode, a thickness of the first metal layer in a direction orthogonal to the first surface being greater than a height of a topmost portion of the lead frame; and
a resin package contacting the semiconductor chip, the first metal layer, at least a portion of the wiring, and a first portion of the first surface and leaving a second portion of the first surface exposed.

15. The semiconductor device according to claim 14, further comprising:
a second metal layer directly attached to a second surface of the semiconductor chip, the second surface being opposite to the first surface, the second metal layer having a thickness in the first direction substantially equal to the thickness of the first metal layer; and
a lead frame portion electrically connected to the second metal layer and having a portion exposed from the resin package.

16. The semiconductor device according to claim 15, wherein
the first metal layer comprises copper, and
the second metal layer comprises copper.

17. The semiconductor device according to claim 15, wherein the first metal layer and the second metal layer each comprises a portion of a copper plate press bonded to a wafer that is divided into the semiconductor chip and a plurality of other semiconductor chips.

18. The semiconductor device according to claim 14, wherein the first metal layer is one of an electrically plated layer or an electrolessly plated layer.

19. The semiconductor device according to claim 14, wherein the first electrode is connected to the wiring by a reflow soldering.

20. The semiconductor device according to claim 14, wherein
the first metal layer is electrically connected to the second electrode by an alloy of gold and tin.
